(19) United States
(12) Patent Application Publication
(10) Pub. No.: US 2007/0273908 A1
(43) Pub. Date: Nov. 29, 2007

(54) Image processing apparatus, printing apparatus, image processing method, color correction table setting method, and printing method.

(76) Inventor: Jun Hoshii, Nagano-ken (JP)

Correspondence Address: MARTINE PENILLA & GENCARELLA, LLP, 710 LAKEWAY DRIVE, SUITE 200, SUNNYVALE, CA, 94085, US

(21) Appl. No.: 11/805,991

(22) Filed: May 24, 2007

(30) Foreign Application Priority Data
May 24, 2006 (JP) P2006-143740
Apr. 24, 2007 (JP) P2007-113829

(51) Int. Cl. G03F 3/08

(52) U.S. Cl. 358/1.9; 358/518

(57) ABSTRACT

An image processing method of processing color image data includes: holding a correction object color which is a color to be corrected and a correction value of the correction object color at least at a time when starting an operation of correcting the color image data; generating a correction area including a coordinate point corresponding to the correction object color in a predetermined color space; generating a correction characteristic that the color is corrected within the correction area and the correction value decreases as it gets closer to an edge of the correction area from the coordinate point of the correction object color, based on the correction object color and the correction value; and correcting the color image data in accordance with the generated correction characteristic.

### BACKGROUND

1. Technical Field

The present invention relates to a technique of correcting color image data so as to obtain desirable colors at the time of outputting a color image on the basis of the color image data.

2. Related Art

Thanks to advancement in technologies of displaying or printing color images, these days, even users not having special knowledge or techniques can display the color images on monitors or outputting the color images by the use of printers, so long as they can acquire color image data.

Since the monitors are different from the printers in methods of expressing colors, they have different ranges of expressible colors. However, thanks to advancement in color management technologies, it is possible to output color images which seem to have substantially the same colors, whether the color images are displayed on the monitors or printed with the printers.

However, the colors of the color images displayed or printed in this way are not colors that satisfy all the users. Accordingly, there have been suggested techniques of enabling a color image to be output with colors desired by the individual users by preparing in advance plural kinds of tone curves for adjusting the colors and selecting one tone curve therefrom (see JP-A-2001-298631 and JP-A-2002-262304) Here, the tone curve means a one-dimensional numerical table in which input gradation values are correlated with output gradation values.

However, there is a problem in that it is not easy to properly correct colors. For example, much knowledge and experience on color management are required for correcting the colors to obtain desired colors by the use of the tone curves. Accordingly, there is a problem in that it is not easy to correct the colors to obtain a desired color image.

### SUMMARY

An advantage of some aspects of the invention is to provide a technique capable of easily correcting colors of a color image.

According to an aspect of the invention, there is provided an image processing method of processing color image data, comprising:

holding a correction object color which is a color to be corrected and a correction value of the correction object color at least at a time when starting an operation of correcting the color image data;

generating a correction area including a coordinate point corresponding to the correction object color in a predetermined color space;

generating a correction characteristic that the color is corrected within the correction area and the correction value decreases as it gets closer to an edge of the correction area from the coordinate point of the correction object color, based on the correction object color and the correction value; and

correcting the color image data in accordance with the generated correction characteristic.

The present disclosure relates to the subject matter contained in Japanese patent application Nos. 2006-143740 filed on May 24, 2006 and 2007-113829 filed on Apr. 24, 2007, which are expressly incorporated herein by reference in its entirety.

### BRIEF DESCRIPTION OF THE DRAWINGS

The invention will be described with reference to the accompanying drawings, wherein like numbers reference like elements.

FIG. 1 is an explanatory diagram schematically illustrating a printing apparatus mounted with an image processing apparatus according to an embodiment of the invention.

FIG. 2 is a perspective view illustrating an appearance of the printing apparatus according to the embodiment.

FIG. 3 is an explanatory diagram illustrating a state where a document table cover disposed in an upper portion of the printing apparatus is opened to read a document image.

FIG. 4 is a perspective view illustrating a state where a front portion of a scanner unit is pushed up to rotate.

FIG. 5 is an explanatory diagram conceptually illustrating an inner configuration of the printing apparatus according to the embodiment.

FIG. 6 is an explanatory diagram illustrating a state where plural nozzles for ejecting ink droplets are formed in an ink ejection head of each color.

FIG. 7 is a flowchart illustrating a flow of an image printing process performed to print an image by the use of the printing apparatus according to the embodiment.

FIG. 8 is an explanatory diagram illustrating a state where it is specified from a screen on an operation panel whether a color correction table should be set before printing an image.

FIG. 9 is an explanatory diagram conceptually illustrating the color correction table referred to in a color correction process.

FIG. 10 is an explanatory diagram conceptually illustrating a color conversion table referred to in a color conversion process.

FIG. 11 is an explanatory diagram illustrating a part of a dither matrix.

FIG. 12 is an explanatory diagram conceptually illustrating a state where it is determined whether a dot should be formed every pixel with reference to the dither matrix.

FIG. 13 is a flowchart illustrating a flow of a color correction table setting process according to a first embodiment of the invention.

FIG. 14 is an explanatory diagram illustrating a state where a correction object color is selected from plural candidate colors.

FIG. 15 is an explanatory diagram conceptually illustrating a state where a correction target color is selected from plural candidate colors set for the correction object color.

FIG. 16 is an explanatory diagram conceptually illustrating a correction area set to include the correction object color.

FIG. 17 is a flowchart illustrating a flow of a color correction table setting process according to a second embodiment of the invention.

FIG. 18 is an explanatory diagram illustrating a state where a candidate color is selected in the color correction table setting process according to the second embodiment.

FIG. 19 is an explanatory diagram illustrating a state where a correction object color is set in a color image to be printed in a color correction table setting process according to a first modified example.

FIG. 20 is an explanatory diagram conceptually illustrating a correction area set to include the correction object color and the correction target color in a color correction table setting process according to a second modified example.

### DESCRIPTION OF EXEMPLARY EMBODIMENTS

Hereinafter, embodiments of the invention will be described in the following order so as to clarify the above-mentioned configurations of the invention:

### A. Summary of Embodiments

### B. Configurations

B-1. Entire Configuration

B-2. Inner Configuration
B-2-1. Inner Configuration of Scanner Unit
B-2-2. Inner configuration of Printer Unit

### C. Image Printing Process

### D. Color Correction Table Setting Process according to First Embodiment

### E. Color Correction Table Setting Process according to First Embodiment

### F. Modified Examples

(1) First Modified Example
(2) Second Modified Example.

### A. SUMMARY OF EMBODIMENTS

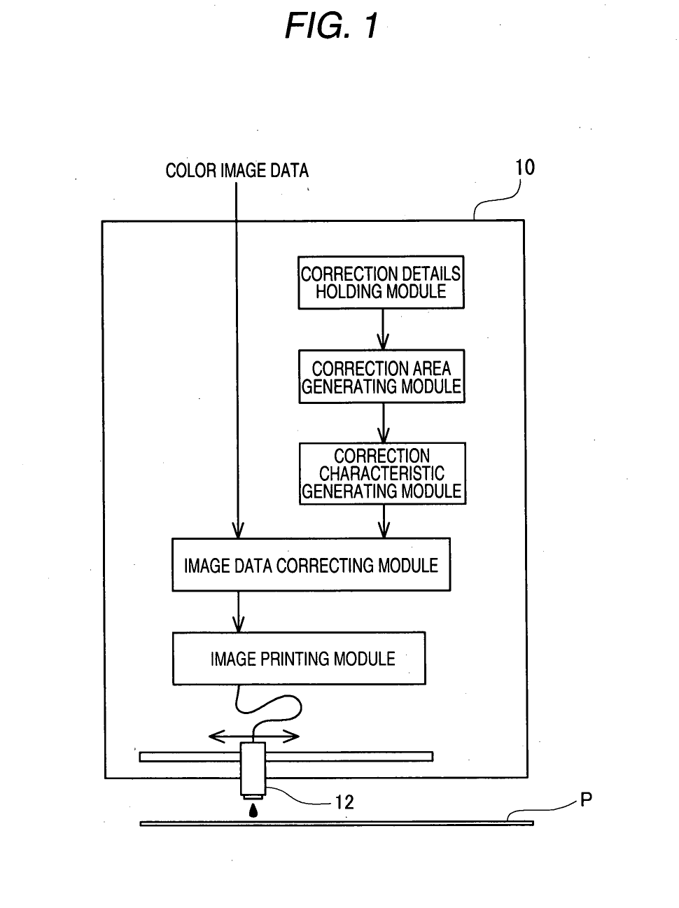

Before describing the embodiments in detail, the summary of the embodiments will be first described reference to FIG. 1. FIG. 1 is an explanatory diagram illustrating an outline of a printing apparatus 10 mounted with an image processing apparatus according to an embodiment of the invention. The printing apparatus 10 is provided with a print head 12 for ejecting ink droplets and is a so-called ink jet printer that forms ink droplets to print an image by ejecting the ink droplets while allowing the print head 12 to reciprocate over a printing medium P. Such a printing apparatus is mounted with plural colors of ink such as a cyan (C) color, a magenta (M) color, and a yellow (Y) color and can print a color image in which colors expressed by color image data are precisely reproduced by ejecting an appropriate amount of ink in accordance with the color image data.

Here, it is convenient to simply correct the colors at the time of outputting the color image. Therefore, the printing apparatus 10 is mounted with modules such as a “correction details holding module”, a “correction area setting module”, a “correction characteristic generating module”, an “image data correcting module”, and an “image printing module.” Here, the “modules” are obtained by classifying a series of processes performed internally to print an image by the printing apparatus 10 depending on functions thereof. Accordingly, the “modules” may be embodied as a part of a program, or may be embodied by using logical circuits having a specific function, or may be embodied by combining them.

In the printing apparatus 10, a color to be corrected (correction object color) and a correction value to be applied to the color are held in the “correction details holding module” in advance at least until the correction of the color image data is started. For example, when it is assumed that a user prefers a color containing a slight orange color to a red color, “red” is held as the correction object color and an intention to emphasize a yellow component by a desired amount is held as the correction value. Of course, plural colors may be held as the correction object color. The correction details (that is, the correction object color and the correction value) may be read and held from details stored therein in advance or may be set externally.

The “correction area generating module” acquires the correction details (the correction object color and the correction value) held in the “correction details holding module” and generates a correction area in which the correction details are reflected. The correction area is generated so as to include a coordinate point of the correction object color in a color space. When plural correction object colors are stored, the correction area is generated every color. A size of the correction area (that is, a range in which the correction details are reflected in the color space) may be changeable.

Subsequently, the “correction characteristic generating module” generates a correction characteristic of a color within the generated correction area. The correction characteristic is set so that the correction value decreases as it gets closer to the outer edge of the correction area from the coordinated point of the correction object color.

In a state where the correction characteristic is set in this way, when the color image data is input to the printing apparatus 10, the “image data correcting module” corrects the color image data in accordance with the correction characteristic and then supplies the corrected color image data to the “image printing module.” The “image printing module” determines an amount of ink to be ejected by performing a predetermined process on the corrected color image data and ejects ink droplets by driving the print head 12. As a result, a color image is printed on the printing medium.

In this way, when the color is corrected and the color image is printed, the correction details are limited to the correction area or the vicinity thereof and thus do not affect the entire image. Accordingly, even a user not having special knowledge or sufficient experience can easily correct a hue of a color image in accordance with his taste to obtain a more desirable color image. Next, the printing apparatus 10 will be described in detail with reference to the embodiments.

### B. CONFIGURATION

### B-1. Entire Configuration

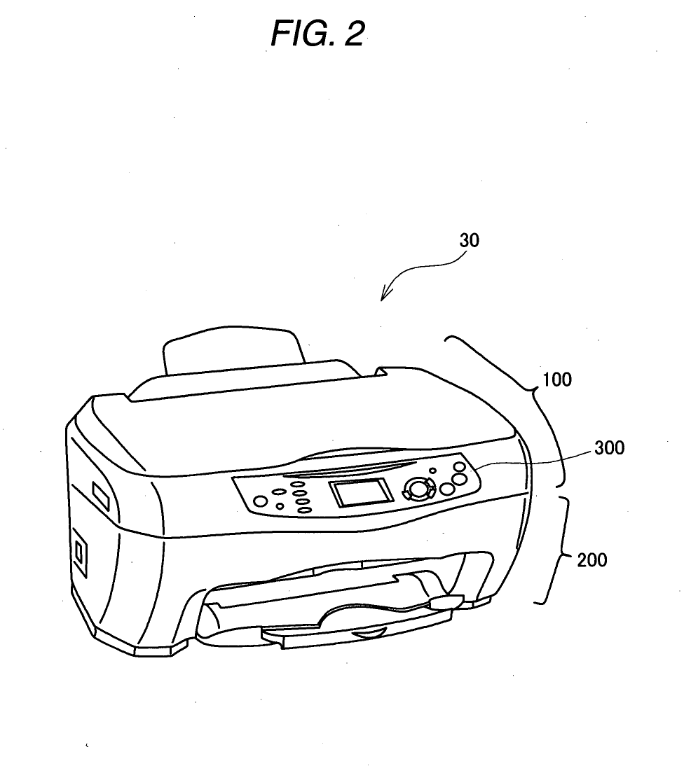

FIG. 2 is a perspective view illustrating an appearance of the printing apparatus 10 according to an embodiment of the invention. As shown in the figure, the printing apparatus 10 includes a scanner unit 100, a printer unit 200, and an operation panel 300 used to set operations of the scanner unit 100 and the printer unit 200. The scanner unit 100 has a scanner function of reading a printed image and generating image data. The printer unit 200 has a printer function of receiving image data to printing an image on a printing medium. By outputting an image (document image) read by the scanner unit 100 to the printer unit 200, a copier function may be embodied. That is, the printing apparatus 10 according to this embodiment is a so-called scanner/printer/copier complex machine (hereinafter, referred to as an SPC complex machine) capable of performing the scanner function, the printer function, and the copier function independently.

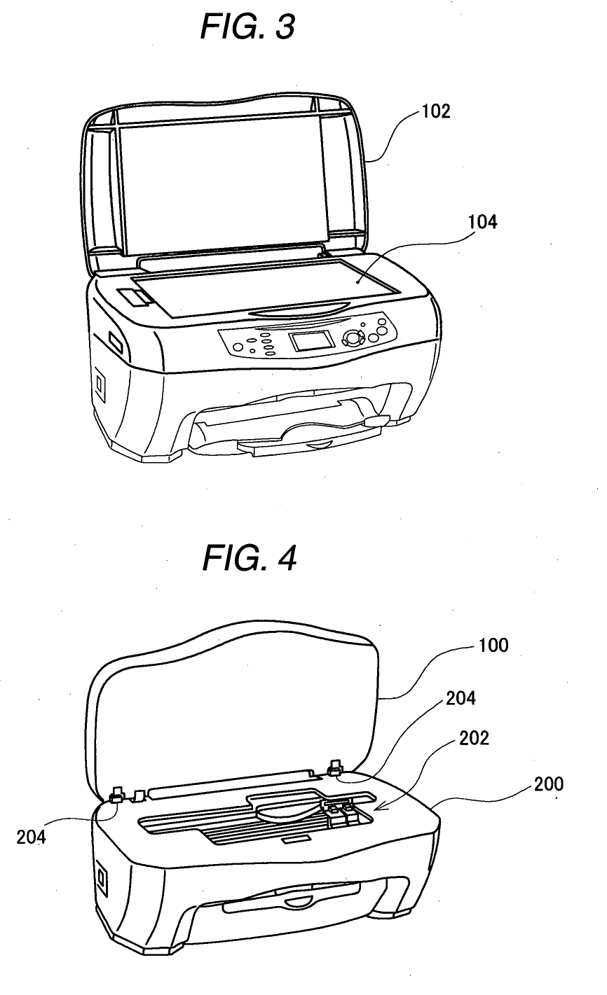

FIG. 3 is an explanatory diagram illustrating a state where a document table cover 102 disposed in the upper portion of the printing apparatus 10 is opened to read a document image. As shown in the figure, when the document table cover 102 is pushed up, a transparent document table glass 104 is provided and various mechanisms to be described later for performing the scanner function are mounted therein. When it is intended to read a document image, as shown in the figure, the document table cover 102 is opened, a document is placed on the document table glass 104, the document table cover 102 is closed, and then buttons on the operation panel 300 are operated. In this way, it is possible to right convert the document image into image data.

The scanner unit 100 is received in a case as a whole. The scanner unit 100 and the printer unit 200 are coupled to each other in a rear portion of the printing apparatus 10 by means of a hinge mechanism 204 (see FIG. 4). Accordingly, by pushing up a front portion of the scanner unit 100, only the scanner unit 100 can be made to rotate at the hinge portion.

FIG. 4 is a perspective view illustrating a state where the front portion of the scanner unit 100 is pushed up to rotate. As shown in the figure, in the printing apparatus 10, the top surface of the printer unit 200 can be exposed by pushing up the front portion of the scanner unit 100. The inside of the printer unit 200 is provided with various mechanisms to be described later for performing the printer function, a control circuit 260 to be described later for controlling the entire operations of the printing apparatus 10 including the scanner unit 100, a power supply circuit (not shown) for supplying power to the scanner unit 100 and the printer unit 200. As shown in FIG. 4, an opening 202 is formed in the top surface of the printer unit 200 and thus it is possible to simply perform an interchange of expendable items such as ink cartridges, a paper jam treatment, and other trifling repairs.

### B-2. Inner Configuration

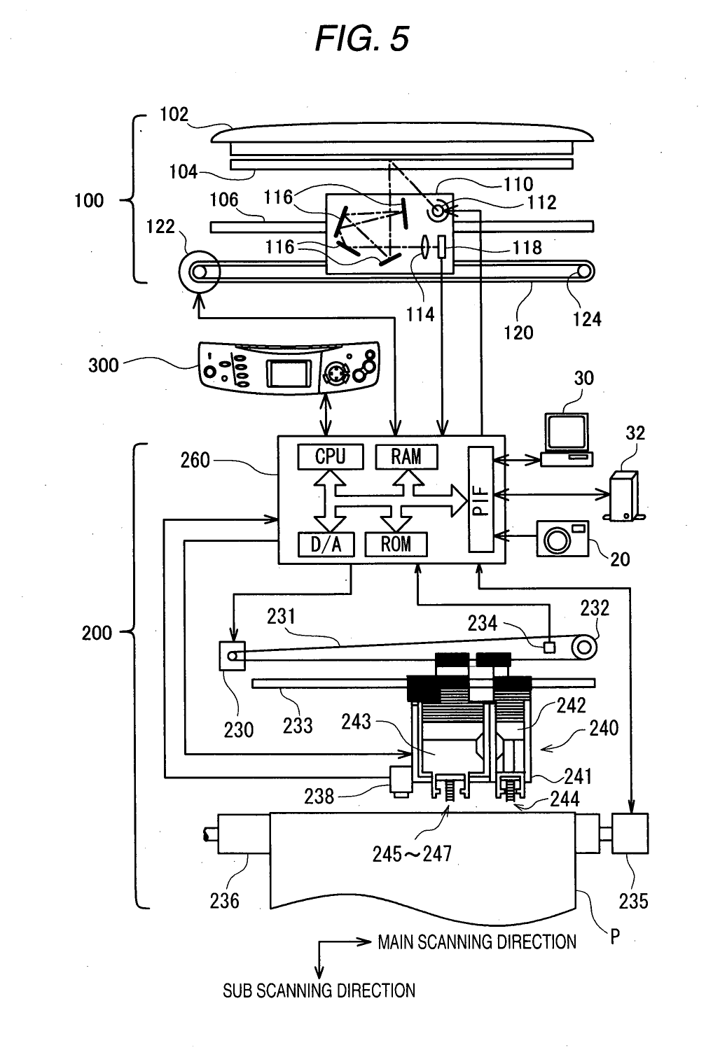

FIG. 5 is an explanatory diagram conceptually illustrating an inner configuration of the printing apparatus 10 according to the embodiment. As described above, the printing apparatus 10 is provided with the scanner unit 100 and the printer unit 200, the inside of the scanner unit 100 is mounted with various configurations for performing the scanner function, and the inside of the printer unit 200 is mounted with various configurations for performing the printer function. Now, the inner configuration of the scanner unit 100 is first described and then the inner configuration of the printer unit 200 is described.

### B-2-1. Inner Configuration of Scanner Unit

The scanner unit 100 includes a transparent document table glass 104 on which a document is set, a document table cover 102 for pressing the set document, a reading carriage 110 for reading an image of the set document, a driving belt 120 for moving the reading carriage 110 in a reading direction (main scanning direction), a driving motor 122 for supplying power to the driving belt 120, and a guide shaft 106 for guiding the movement of the reading carriage 110. Operations of the driving motor 122 and the reading carriage 110 are controlled by a control circuit 260 to be described later.

When the driving motor 122 is rotated under the control of the control circuit 260, the movement thereof is transmitted to the reading carriage 110 through the driving belt 120 and the reading carriage 110 is guided by the guide shaft 106 so as to move in the reading direction (main scanning direction) in response to a rotation angle of the driving motor 122. The driving belt 120 is adjusted to be always tight by an idler pulley 124. Accordingly, by reversely rotating the driving motor 122, it is possible to reversely move the reading carriage 110 by a distance corresponding to the rotation angle.

The inside of the reading carriage 110 is mounted with a light source 112, a lens 114, mirrors 116, a CCD sensor 118, and the like. Light from the light source 112 is radiated on to the document table glass 104 and is reflected by the document image set on the document table glass 104. The reflected light is guided to and concentrated on the lens 114 by the mirrors 116 and then is detected by the CCD sensor 118. The CCD sensor 118 is composed of a linear sensor in which photodiodes for converting light intensity into an electrical signal are arranged linearly in a direction perpendicular to the movement direction (main scanning direction) of the reading carriage 110. Accordingly, by radiating light from the light source 112 to the document image while moving the reading carriage 110 in the main scanning direction and then detecting the intensity of the reflected light by the use of the CCD sensor 118, it is possible to obtain the electrical signal corresponding to the document image.

The light source 112 is composed of three-color light-emitting diodes of RGB and can sequentially radiate R light, G light, and B light with a predetermined period. Accordingly, the CCD sensor 118 can sequentially detect the R light, the G light, and the B light. In general, since a red portion of an image reflects the R light but hardly reflects the G light and the B light, the reflected R light represents an R component of the image. Similarly, the reflected G light represents a G component of the image and the reflected B light represents a B component of the image. Accordingly, by sequentially radiating the three-color light of RGB to the document image with a predetermined period and detecting the intensity of the reflected light by the use of the CCD sensor 118 in synchronization therewith, it is possible to detect the R component, the G component, and the B component of the document image, thereby reading the color image. Since the reading carriage 110 moves while the light source 112 changes the color light to be radiated, the positions of the image of which the RGB components are detected are strictly different by a distances corresponding to the moving distances of the reading carriage 110, but the differences can be corrected by means of an image process after reading the components.

### B-2-2. Inner Configuration of Printer Unit

Next, an inner configuration of the printer unit 200 will be described. The printer unit 200 is mounted with the control circuit 260 for controlling the entire operations of the printing apparatus 10, a print carriage 240 for printing an image on a printing medium, a mechanism for moving the print carriage 240 in the main scanning direction, and a mechanism for transporting the printing medium.

The print carriage 240 includes an ink cartridge 242 for receiving K ink, an ink cartridge 243 for receiving various color inks such as C ink, M ink, and Y ink, and a print head 241 disposed close to the bottom surface. An ink ejection head for ejecting ink droplets is disposed in the print head 241 every ink. When the ink cartridges 242 and 243 are mounted on the print carriage 240, the ink in the cartridges is supplied to the ink ejection head 244 for each color through a supply tube not shown.

The mechanism for moving the print carriage 240 in the main scanning direction includes a carriage belt 231 for driving the print carriage 240, a carriage motor 230 for supplying power to the carriage belt 231, a tension pulley 232 for always applying a proper tension to the carriage belt 231, a carriage guide 233 for guiding the movement of the print carriage 240, and an origin position sensor 234 for detecting an origin position of the print carriage 240. By rotating the carriage motor 230 under the control of the control circuit 260 to be described later, it is possible to move the print carriage 240 in the main scanning direction by a distance corresponding to the rotation angle. By reversely rotating the carriage motor 230, it is also possible to reversely move the print carriage 240.

The mechanism for transporting the printing medium such as a sheet of paper includes a platen 236 for supporting the printing medium from the back surface and a paper transport motor 235 for rotating the platen 236 to transport the printing medium. By rotating the paper transport motor 235 under the control of the control circuit 260 to be described later, it is possible to transport the printing medium in a sub scanning direction by a distance corresponding to the rotation angle.

The control circuit 260 includes a CPU, a ROM or RAM, a D/A converter for converting digital data into analog signals, and peripheral device interface PIF for transmitting and receiving data to and from peripheral devices. The control circuit 260 controls the entire operations of the printing apparatus 10 and controls the operations of the light source 112, the driving motor 122, and the CCD sensor 118 mounted on the scanner unit 100 while exchanging data therewith.

The control circuit 260 also performs a control operation of supplying driving signals to the ink ejection heads 244 to 247 for the colors to eject the ink droplets while driving the carriage motor 230 and the paper transport motor 235 to move the print carriage 240 in the main scanning direction and the sub scanning direction. The driving signals supplied to the ink ejection heads 244 to 247 are generated by reading image data from a computer 30, a digital camera 20, an external storage 32, and the like and performing an image process to be described later. Of course, the driving signals may be generated by performing an image process on the image data read by the scanner unit 100. Under the control of the control circuit 260, it is possible to print a color image by ejecting the ink droplets from the ink ejection heads 244 to 247 to for ink dots of the colors on the printing medium while moving the print carriage 240 in the main scanning direction and the sub scanning direction. Of course, data having been subjected to an image process may be received from the computer 30 instead of allowing the control circuit to perform the image process and the ink ejection heads 244 to 247 may be driven while moving the print carriage 240 in the main scanning direction and, the sub scanning direction in accordance with the data.

The control circuit 260 is connected to the operation panel 300 so as to transmit and receive data thereto and therefrom. Detailed operation modes of the scanning function and the printer function can be set by operating various buttons disposed on the operation panel 300. Furthermore, the detailed operation modes can be also set through the peripheral device interface PIF by the computer 30.

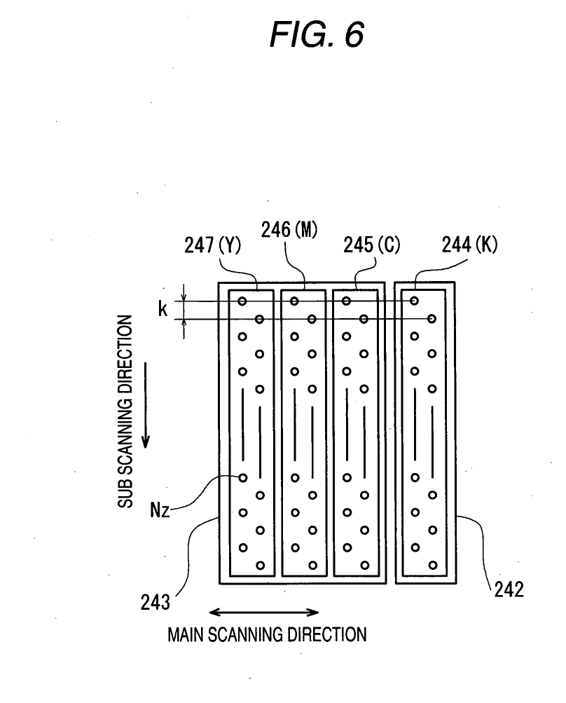

FIG. 6 is an explanatory diagram illustrating a state where plural nozzles Nz for ejecting ink droplets are formed in the ink ejection heads 244 to 247 for the colors. As shown in the figure, 4 sets of nozzle lines for ejecting the ink droplets of each color are formed in the bottom surface of the ink ejection head for the corresponding color and 48 nozzles Nz are arranged in a staggered pattern at a nozzle pitch k in one nozzle line. The driving signals are supplied to the respective nozzles Nz from the control circuit 260 and the respective nozzles Nz eject the ink droplets of each ink in response to the driving signals.

As described above, the printer unit 200 of the printing apparatus 10 prints an image by supplying the driving signals to the nozzles for ejecting ink and ejecting the ink droplets in response to the driving signals to form the ink dots on the printing medium. Control data for driving the ink ejecting nozzles are generated by performing a predetermined image process on the image data before printing the image. Hereinafter, a process (image printing process) of performing an image process on the image data to generate the control data and forming the ink dots on the basis of the generated control data will be described.

### C. IMAGE PRINTING PROCESS

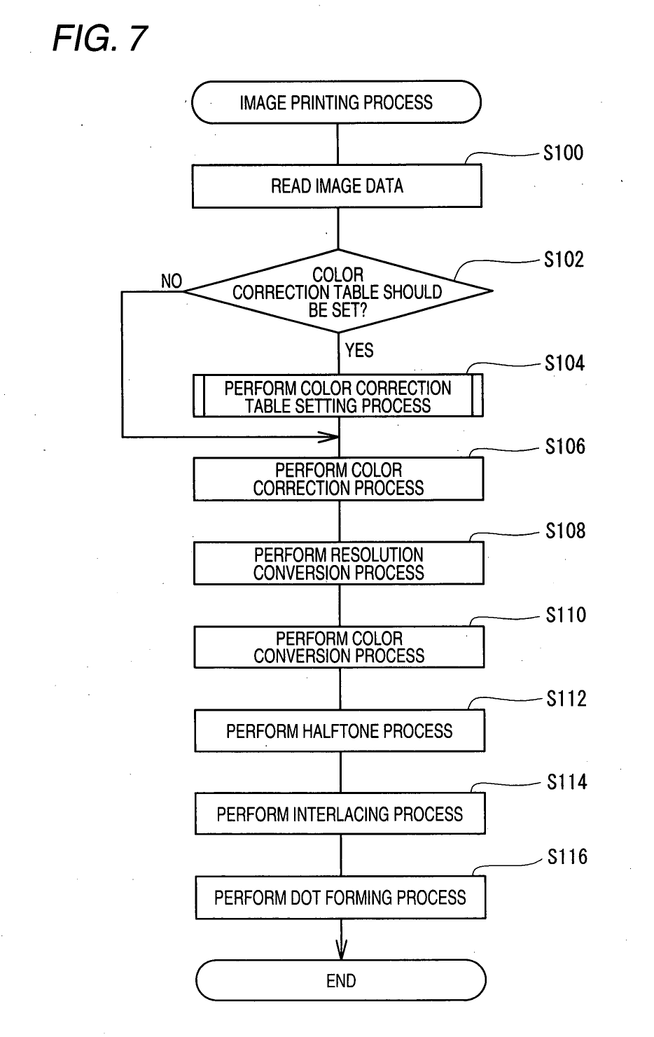

FIG. 7 is a flowchart illustrating a flow of an image printing process performed to print an image by the use of the printing apparatus 10 according to the embodiment. Such a process is performed by the control circuit 260 mounted on the printing apparatus 10 by the use of the functions of the built-in CPU, RAM, ROM, and the like. Now, the process is described with reference to the flowchart.

The control circuit 260 first reads image data to be printed at the time of starting the image printing process. Here, the image data is assumed as RGB image data expressed by gradation values of the R, G. and B colors.

It is determined whether a color correction table should be set (step S102). Here, the color correction table is a table used to correct color image data so as to print a color image with more desirable colors. As described later, the RGB image data and after-correction RGB image data are correlated with each other and stored in the color correction table. By converting the RGB image data with reference to the color correction table, it is possible to print the color image with more desirable colors. In the printing apparatus 10 according to the embodiment, it can be specified from the operation panel 300 whether the colors should be corrected to desired colors before printing an image or whether the color correction table used for the correction should be set.

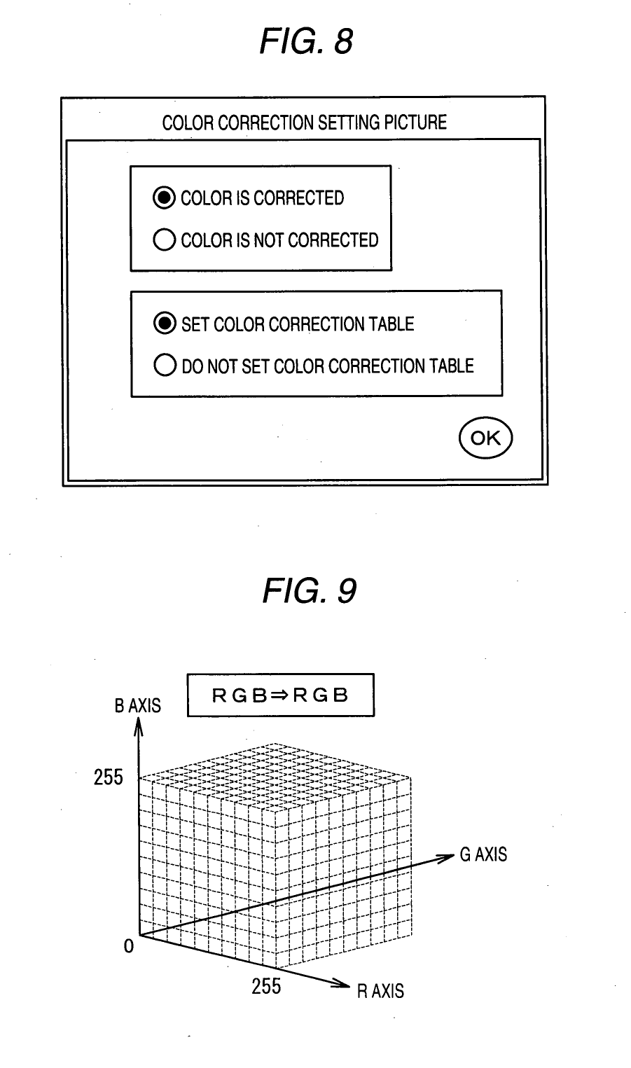

FIG. 8 is an explanatory diagram illustrating a state where it is specified from the screen on the operation panel 300 whether the color correction table should be set before printing an image. As shown in the figure, by selecting a corresponding radio button on the screen of the operation panel 300, it can be specified whether the colors should be corrected and whether the color correction table should be set. When it is selected that the colors should be corrected but the color correction table should not be set, a color correction process to be described later is performed with reference to an existing color correction table previously stored in the printing apparatus 10. Here, the existing color correction table may be a color correction table previously set by a user or a color correction table previously supplied as a standard to the printing apparatus 10.

On the other hand, when it is specified that the color correction table should be set, it is determined that the color correction table should be set (Yes in step S102 of FIG. 7) and a color correction table setting process is started (step S104). Details of the color correction table setting process will be described later. On the contrary, when it is determined that the color correction table should not be set (No in step S102), the color correction table setting process is skipped and the color correction process is directly started (step S106). When it is specified that the colors should not be corrected before printing an image, the color correction process is also skipped.

FIG. 9 is an explanatory diagram conceptually illustrating the color correction table referred to in the color correction process. It is assumed that an RGB color space is set by three axes perpendicular to each other and the RGB image data is represented as coordinate points in the RGB color space. When it is assumed that the RGB image data is 1 byte data, all the RGB image data can be made to correspond to coordinate points in a cubic having a side length of 255. In other words, all the coordinate points in the cubic having a side length of 255 can be made to correspond to one RGB image data. That is, the respective lattice points which can be obtained by finely dividing the cubic in lattice patterns can be considered as representing RGB image data, and a color represented by the RGB image data can be corrected to obtain new RGB image data. The color correction table can be considered as a kind of numerical table in which after-correction RGB image data is set to the lattice points disposed in the RGB color space. With reference to the color correction table, it is possible to convert the RGB image data into RGB image data with more desirable colors. For example, when a coordinate point of input RGB image data corresponds to a lattice point, it is possible to directly obtain the after-correction RGB image data by only reading the RGB image data set to the lattice point. When the coordinate point of the input RGB image data does not correspond to any lattice point, it is possible to obtain the after-correction RGB image data by performing an interpolating operation using the RGB image data set to the neighboring lattice points.

In the color correction process (step S106) of the image printing process shown in FIG. 7, a process of converting the RGB image data is performed by referring to the table when it is specified that the color correction table should be set (Yes in step S102) and referring to the color correction table stored in the RAM of the control circuit 260 when it is specified that the color correction table should not be set (No in step S102).

Subsequently, in the image printing process, a process of converting a resolution of the RGB image data into a resolution (printing resolution) of the printing operation of the printer unit 200 is performed (step S108). When the resolution of the RGB image data is lower than the printing resolution, the resolution of the RGB image data is converted into a higher resolution by performing an interpolating operation on the neighboring pixels to generate new image data. On the contrary, when the resolution of the RGB image data is higher than the printing resolution, the resolution of the RGB image data is converted into a lower resolution by thinning out image data between the neighboring pixels at a constant ratio. In the resolution converting process, the process of converting the read resolution into the printing resolution is performed by generating or thinning out image data from the read image data at a proper ratio.

In this way, when the resolution of the RGB image data is converted into the printing resolution, a color conversion process is performed (step S110). Here, the color conversion process means a process of converting image data expressed by R, G, and B colors into image data expressed by gradation values of C, M, Y, and K colors. The color conversion process is performed with reference to a three-dimensional numerical table called a color conversion table (LUT).

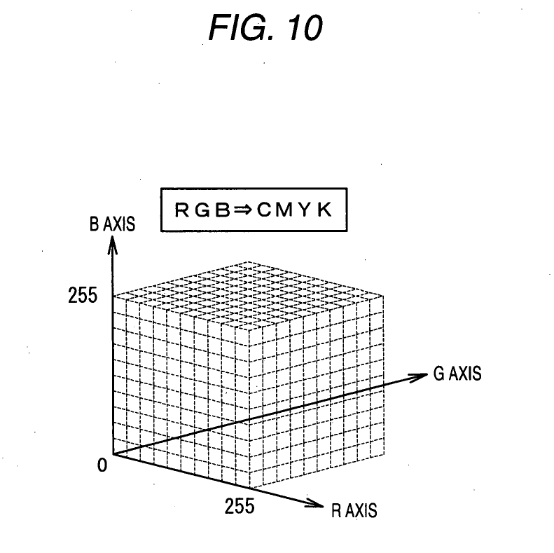

FIG. 10 is an explanatory diagram conceptually illustrating the color conversion table (LUT) referred to in the color conversion process. In the color correction table described above with reference to FIG. 9, the RGB image data is set at the lattice points in the RGB color space. On the contrary, in the color conversion table, gradation data of the CMYK colors (hereinafter, referred to as CMYK image data) corresponding to the RGB image data at the lattice points is set. The RGB image data can be rapidly converted into the CMYK image data by referring to the color conversion table. That is, when the RGB image data is received, it is determined whether the coordinate point corresponding to the image data corresponds to the lattice point in the color conversion table. When it is determined that the coordinate point corresponds to the lattice point, the CMYK image data set at the lattice point can be obtained. When it is determined that the coordinate point of the RGB image data does not correspond to the lattice point, the CMYK image data can be obtained by performing an interpolating operation based on the CMYK image data set at the neighboring lattice points.

When the color conversion process is ended, the control circuit 260 starts a halftone process (step S112). The halftone process is as follows. The CMYK image data obtained in the color conversion process is image data expressed by C, M, Y, and K colors in the range of gradation values 0 to 255. On the contrary, since the printer unit 200 prints an image by forming dots, a process of the CMYK image data expressed by 256 gradations into image data (dot data) expressed by formation or non-formation of dots is needed. The halftone process is a process of converting the image data of the CMYK colors into the dot data.

The halftone process employs various methods such as an error diffusion method and a dither method. The error diffusion method is a technique of determining the formation or non-formation of a dot every pixel so as to diffuse an error in gradation expression occurring in the corresponding pixel into the neighboring pixels and to release errors diffused from the neighboring pixels. The dither method is a technique of acquiring the dot data of each pixel by comparing the CMYK image data with threshold values randomly set in a dither matrix every pixel, determining that a dot should be formed in a pixel having the larger image data value, and determining that a dot should not be formed in a pixel having a larger threshold value. The halftone process can employ any one of the error diffusion method and the dither method, but the printing apparatus 10 according to this embodiment performs the halftone process using the dither method.

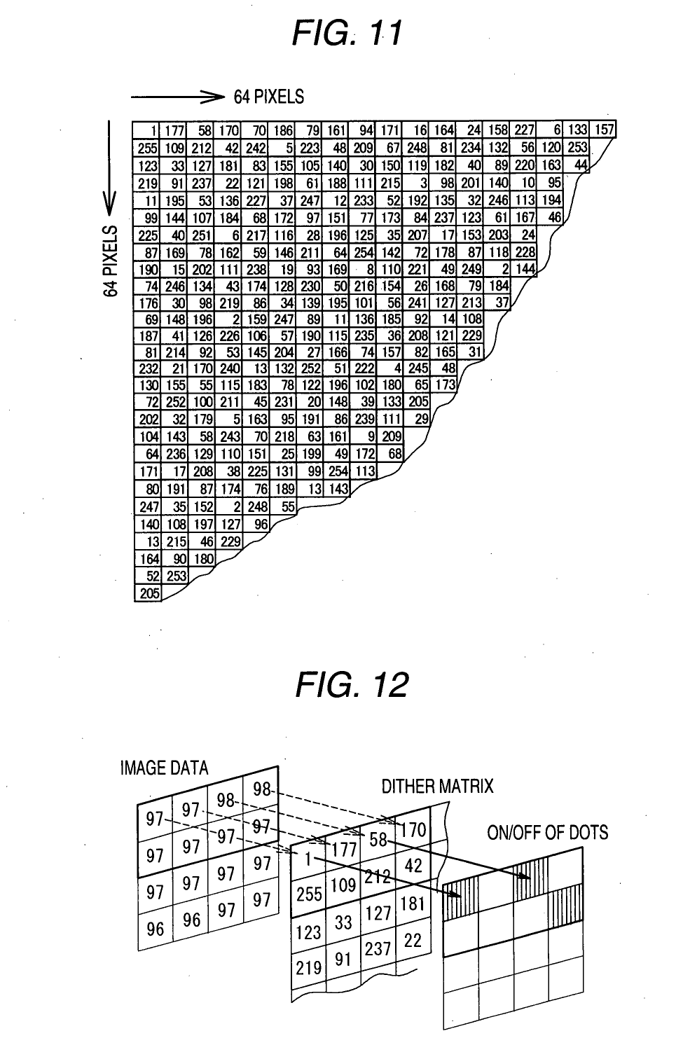

FIG. 11 is an explanatory diagram illustrating a part of the dither matrix. In the shown matrix, threshold values selected uniformly from the range of gradation values 0 to 255 are randomly stored in 4096 pixels in total of 64×64 pixels. Here, the reason for selecting the threshold values from the range of gradation values 0 to 255 is that the CMYK image data after the color conversion is 1 byte data and the gradation values can have 0 to 255 in this embodiment. The size of the dither matrix is not limited to the 64×64 pixels as shown in FIG. 11, but may be set to various sizes including sizes having the different numbers of pixels in rows and columns.

FIG. 12 is an explanatory diagram conceptually illustrating a state where the formation or non-formation of a dot is determined every pixel. The determination is made for each of the CMYK colors, but for the purpose of avoiding complex description in the following, the image data of the CMYK colors are simply called image data without being distinguished.

At the time of determining the formation or non-formation of a dot, a gradation value of the image data of a pixel (noted pixel) to be determined is compared with a threshold value stored at the corresponding position in the dither matrix. The narrow dotted arrow in the figure schematically shows that the image data of the noted pixel is compared with the threshold value stored at the corresponding position in the dither matrix. When the image data of the noted pixel is larger than the threshold value of the dither matrix, it is determined that a dot should be formed in the pixel. On the contrary, when the threshold value of the dither matrix is larger than the image data of the noted pixel, it is determined that a dot should not be formed in the pixel. In the example shown in FIG. 12, the image data of the pixel located at the left-upper corner of the image is “97” and the threshold value stored at a position corresponding to the pixel in the dither matrix is “1.” Accordingly, since the image data of the left-upper corner pixel is larger than the threshold value of the dither matrix, it is determined that a dot should be formed in the pixel. The solid arrow in FIG. 12 schematically shows that it is determined that a dot should be formed in the pixel and the determination result is stored in a memory.

On the other hand, in a pixel on the right side of the pixel, since the image data of the pixel is “97” and the threshold value of the dither matrix is “177”, the threshold value is larger than the image data. Accordingly, it is determined that a dot should not be formed in the pixel. In this way, by comparing the image data with the threshold values set in the dither matrix, it is possible to determine the formation or non-formation of a dot every pixel. In the halftone process (step S112 of FIG. 7), the process of determining the formation or non-formation of a dot every pixel to generate the dot data by applying the dither method to the image data of the C, M, Y, and K is performed.

As shown in FIG. 7, in the image printing process, an interlacing process is started (step S114), when the dot data of the CMYK colors are generated through the halftone process. The interlacing process is a process of rearranging the dot data in an order in which the print head 241 forms the dots and supplying the rearranged dot data to the ink ejection heads 244 to 247. That is, as shown in FIG. 6, the nozzles Nz of the ink ejection heads 244 to 247 are arranged with a nozzle pitch k in the sub scanning direction. Accordingly, when the ink droplets are ejected while the print carriage 240 is moved in the main scanning direction, dots are formed with the nozzle pitch k in the subs canning direction. Therefore, in order to form the dots in the entire pixels, it is necessary to move the relative position between the print carriage 240 and the printing medium in the sub scanning direction and to form a new dot in a pixel between the dots apart from each other by the nozzle pitch k. In this way, at the time of actually forming an image, the dots are not formed sequentially from the uppermost pixel in the image. A method of not forming all the dots in the pixels of the same line in the main scanning direction by means of one main scanning operation but by means of several main scanning operations and forming the dots in the pixels at outstanding positions in each main scanning operation is widely used.

For these reasons, a process of rearranging the dot data obtained for each of the C, M, Y, and K colors in the order in which the ink ejection heads 244 to 247 form the dots is necessary before starting the actual formation of the dots. This process is called an interlacing process.

As shown in FIG. 7, when the interlacing process is ended, a process of actually forming the dots on the printing medium (dot forming process) on the basis of the dot data rearranged in the interlacing process is started (step S116) That is, the dot data having a rearranged order is supplied to the ink ejection heads 244 to 247 while the carriage motor 230 is driven to move the print carriage 240 in the main scanning direction. As a result, the ink droplets are ejected from the ink ejection heads 244 to 247 in accordance with the dot data to properly form the dots in the pixels.

When one main scanning operation is ended, the dots are formed by supplying the dot data having the rearranged order to the ink ejection heads 244 to 247 while driving the paper transport motor 235 to transport the printing medium in the sub scanning direction and then driving the carriage motor 230 again to move the print carriage 240 in the main scanning direction. By repeating the above-mentioned operation, the dots of the C, M, Y, and K colors are formed on the printing medium with a proper distribution in accordance with the gradation values of the image data, thereby printing a color image.

In the above-mentioned image printing process according to this embodiment, when the RGB image data is received, the colors are corrected by performing the color correction process thereon and then the color image is printed. Accordingly, a user can print the color image with the user's preferable colors. Of course, in order to print the color image with more preferable colors, it is necessary to set an appropriate color correction table. In the printing apparatus 10 according to this embodiment, the color correction table is set as follows. Accordingly, even a user not having special knowledge and experience can appropriately set the color correction table.

### D. COLOR CORRECTION TABLE SETTING PROCESS ACCORDING TO FIRST EMBODIMENT

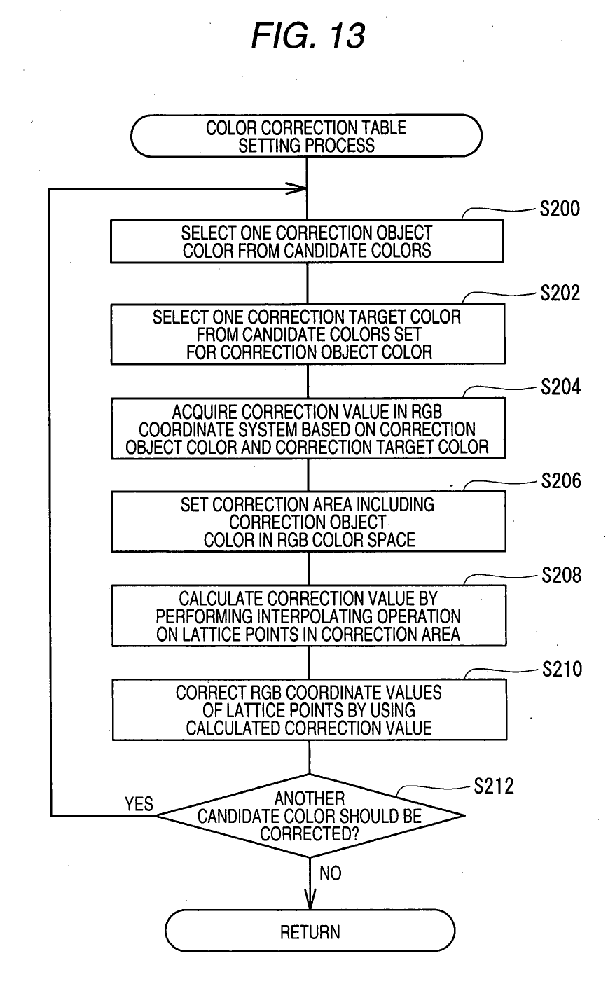

FIG. 13 is a flowchart illustrating a flow of a color correction table setting process according to a first embodiment of the invention. Such a process is a part of the image printing process performed by the control circuit 260. Now, the process is described with reference to the flowchart.

In the color correction table setting process according to the first embodiment, first, one correction object color is selected from candidate colors (step S200). Here, the candidate colors are plural colors set in advance as colors to be corrected. In the color correction table setting process according to the first embodiment, the color correction table is established by selecting a desired colors from the plural colors set as the candidate colors and correcting the selected color.

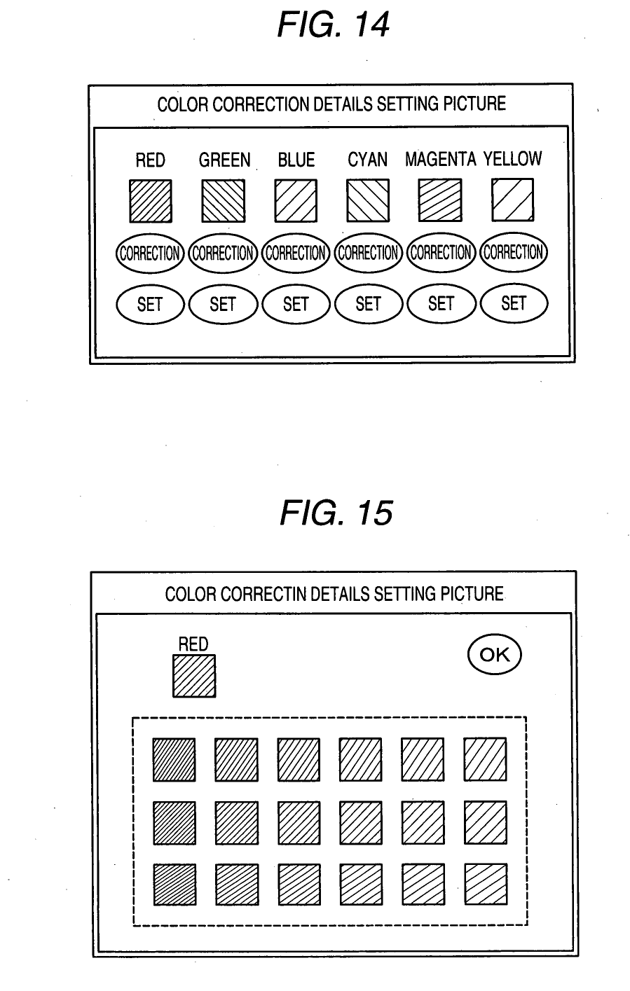

FIG. 14 is an explanatory diagram illustrating a state where a correction object color is selected from plural candidate colors. In the color correction table setting process according to this embodiment, the correction object color is selected from the plural candidate colors disposed on the screen of the operation panel 300. In the shown example, 6 candidate colors of “red”, “green”, “blue”, “cyan”, “magenta”, and “yellow” are prepared and a “correct” button and a “set” button are prepared for each candidate color. The correction object color is selected by selecting any one of the “correct” button and the “set” button. For example, the “correct” button is selected when it is intended to correct the color of “red” displayed on the screen, and the “set” button is selected when the correction is not necessary. Herein, it is assumed that the “correct” button is selected. Then, the screen of the operation panel 300 is completely changed to a picture for selecting a correction target color of the selected correction object color from the picture for selecting the correction object color.

FIG. 15 is an explanatory diagram conceptually illustrating a state where a correction target color is selected from candidate colors set for the correction object color. In the upper portion of the picture, the selected correction object color (“red” in this example) is displayed. Inside a rectangular surrounded with a dotted line in the lower portion of the picture, plural colors having slightly different saturation, hue, or brightness relative to the correction object color are set in advance as the correction candidate colors. The correction target color can be set by selecting a desired color from the plural colors and selecting an “OK” button. In step S202 of FIG. 13, the process of selecting the correction target color of the correction object color is performed in this way.

In the color correction table setting process, a user can specify what color should be corrected. A standard correction target color may be set every correction object color. In this case, only by selecting the correction object color, the user can correct a color using a correction value previously set as a standard in the printing apparatus 10 as the correction value of the color. In addition, the correction object color may be set as a standard and the user may set only the correction value.

On the basis of the correction object color and the correction target color selected in this way, the correction value is acquired (step S204). That is, in the color correction table setting process according to the first embodiment, since the correction object color and the correction target color are both selected from predetermined colors, the RGB image data of the colors can be acquired in advance. When a different between the RGB image data of the correction object color and the RGB image data of the correction target color is calculated, the correction value can be acquired every component.

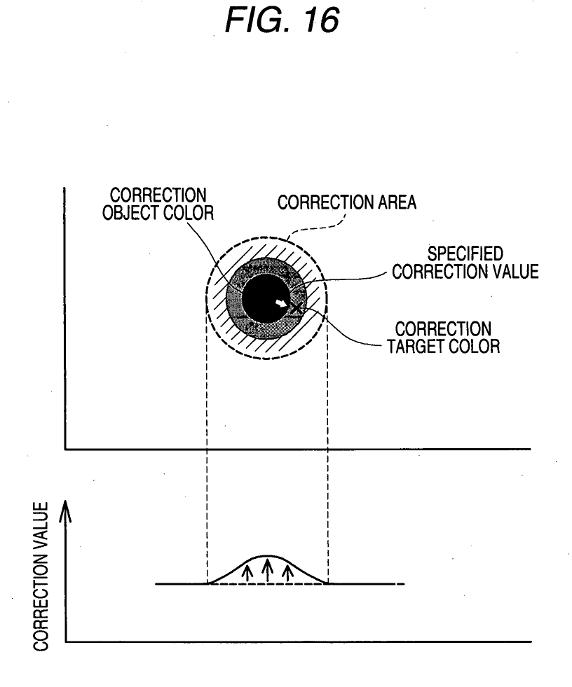

Subsequently, a correction area including the correction object color is set in the RGB color space (step S206). FIG. 16 is an explanatory diagram conceptually illustrating the correction area set to include the correction object color. The correction area is a three-dimensional area set in the RGB color space, but the correction area is shown as a two-dimensional area in FIG. 16 for the purpose of convenient drawing. The size of the correction area is set in advance, but may be changed as needed.

Since the correction area is assumed as being set in the RGB color space, the correction area includes plural lattice points of the color correction table. Therefore, the correction values of the lattice points are calculated (step S208). The calculation of the correction values is performed as follows. First, the correction values of the RGB components calculated in step S204 are set at the coordinate point of the correction object color and “0” is set as the correction values of the components in the boundary of the correction area. Subsequently, under this condition, the correction values of the lattice points are interpolated every component and are calculated so that the correction values smoothly vary in the correction area.

Subsequently, the RGB image data of the lattice points in the color correction table are corrected using the calculated correction values (step S210). That is, a reference table is prepared in advance in which coordinate values of the plural lattice points in the RGB color space are set to the lattice points. The correction values of the components are reflected in the RGB image data set at the lattice points in the reference table. In this way, the color correction table which allows the correction object color (“red” in this example) selected in step S200 to be corrected to a desirable color can be obtained.

Next, it is determined whether another candidate color should be corrected (step S212). When any candidate color of which the “set” button is not selected remains in the picture for selecting the correction object color shown in FIG. 14, it is determined that the candidate color should be corrected (No in step S212). Then, a new correction object color is selected (step S200) and then the above-mentioned series of processes are performed thereon. When these processes are repeated and the “set” buttons of all the candidate colors are selected, it is determined that no candidate color to be corrected exists (Yes in step S212) and then the color correction table setting process according to the first embodiment shown in FIG. 13 is ended.

In the color correction table setting process according to the first embodiment described above, the correction of the correction object color is reflected within the range of the correction area set to include the correction object color. Accordingly, since the correction of any color does not unintentionally affect another color, even a user not having special knowledge and experience can print a color image with corrected desirable colors without spoiling the entire image.

In the color correction table setting process according to the first embodiment, it has been described that a correction value is calculated directly from a difference between the RGB image data of the correction object color and the RGB image data of the correction target color. In this case, since the correction values of the components can be rapidly calculated, it is possible to rapidly set the color correction table and to rapidly correct an image.

However, not limited thereto, the correction object color and the correction target color may be converted into data of an expression type using hue (H component), saturation (S component), and brightness (B component), the correction values of the components may be calculated, and then the correction values of the RGB components may be calculated from the calculated correction values. By calculating the correction values using such a method, it is possible to accurately correct the color, even when only the hue should be corrected with the saturation and the brightness unchanged or when only the saturation should be corrected with the hue and the brightness unchanged.

### E. COLOR CORRECTION TABLE SETTING PROCESS ACCORDING TO SECOND EMBODIMENT

In the color correction table setting process according to the first embodiment, the correction values of the color has been set indirectly by setting a correction object color and a color (correction target color) to be obtained by correcting the correction object color. However, the correction values of the correction object color may be set more directly. Hereinafter, a color correction table setting process according to a second embodiment of the invention will be described.

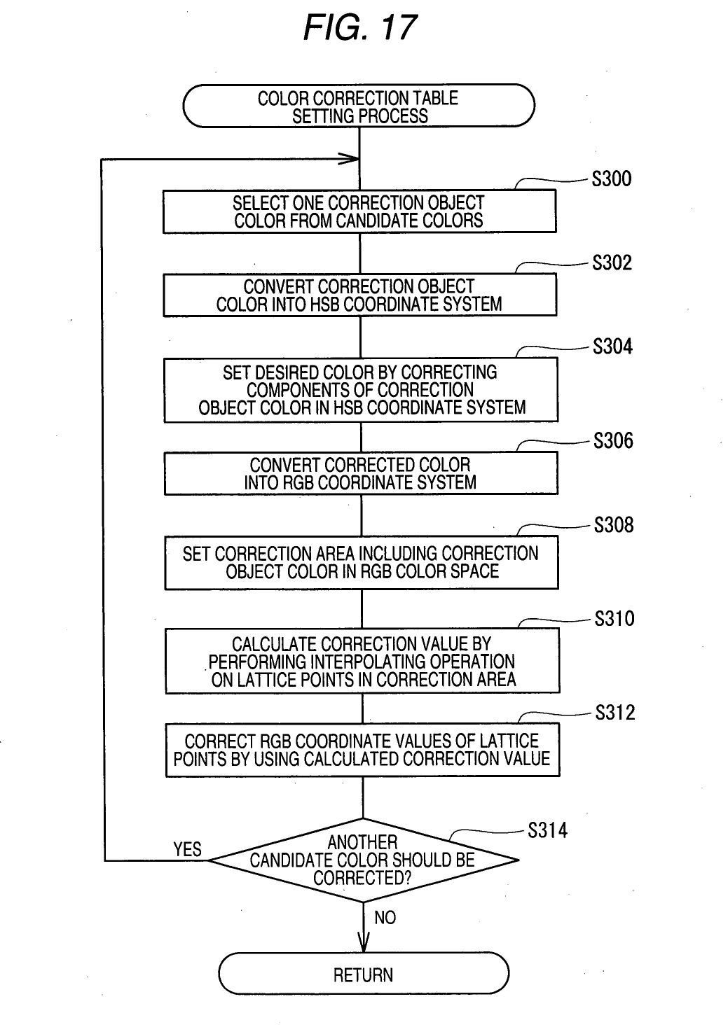

FIG. 17 is a flowchart illustrating a flow of the color correction table setting process according to the second embodiment of the invention. Such a process is a part of the image printing process shown in FIG. 7 and performed by the control circuit 260, similarly to the color correction table setting process according to the first embodiment described above with reference to FIG. 13.

In the color correction table setting process according to the second embodiment, first, one correction object color is selected from candidate colors (step S300), similarly to the color correction table setting process according to the first embodiment. Plural colors are set in advance as the candidate colors and a color to be corrected is selected therefrom.

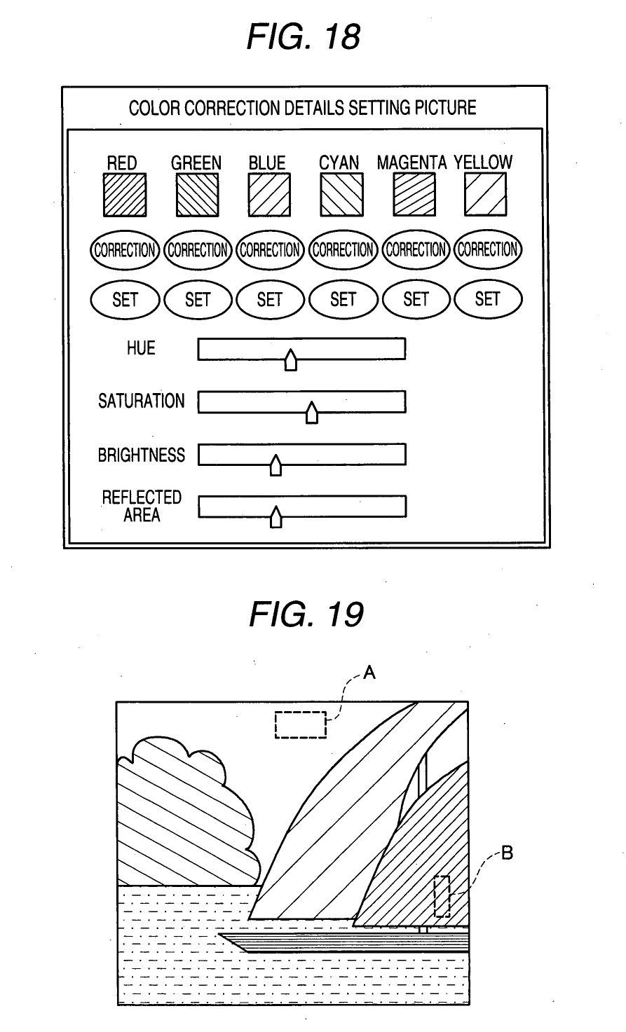

FIG. 18 is an explanatory diagram illustrating a state where a candidate color is selected in the color correction table setting process according to the second embodiment. As shown in the figure, in the printing apparatus 10 according to the second embodiment, plural candidate colors are displayed on the screen of the operation panel 300 and the “correct” button and the “set” button are disposed every candidate color. The “set” button of the color not to be corrected among the candidate colors is selected. On the contrary, by selecting the “correct” button of the color to be corrected, the color is selected as the candidate color.

In this way, when one color of the plural candidate colors is selected as the correction object color, the control circuit 260 performs a process of converting the selected correction object color into image data of an HSB coordinate system (step S302). That is, in the printing apparatus 10, color image data is usually expressed as RGB image data using brightness components of R, G, and B colors, and the RGB image data is converted into color image data (HSB image data) expressed by an H component (hue component), an S component (saturation component), and a B component (brightness component). The conversion of the RGB image data into the HSB image data can be easily performed using a known conversion equation.

Subsequently, a desired color is set by correcting all or one of the H component, the S component, and the B component of the correction object color converted in the HSB coordinate system (step S304). As shown in FIG. 18, the operation panel 300 of the second embodiment is provided with slide bars for adjusting the hue component, the saturation component, and the brightness component and the hue component, the saturation component, and the brightness component can be independently adjusted by moving an indicator of each slide bar horizontally. The adjustment result using the indicators of the slide bars is reflected in the correction object color displayed on the upper portion of the operation panel 300. For example, when “red” is selected as the correction object color, the movement of the indicators of the slide bars is reflected in the red hue, the saturation, and the brightness.

In this way, when a desired color is obtained by setting the hue component, the saturation component, and the brightness component in the correction values of the correction object color while confirming the display on the operation panel 300, the correction values are set by selecting the “set” button. Then, the components of the HSB image data of the correction object color are corrected on the basis of the positions of the indicators of the slide bars and then the corrected HSB image data is converted into the RGB image data (step S306). Similarly to the conversion of the RGB image data into the HSB image data, the conversion of the HSB image data into the RGB image data can be easily performed using a known conversion equation.

In this way, when the RGB image data of the correction object color and the RGB image data of the desired color (that is, correction target color) are obtained, the same subsequent processes as the color correction table setting process according to the first embodiment can be performed. That is, as shown in FIG. 16, the correction area including the correction object color is set in the RGB color space (step S308). Subsequently, the correction values are calculated by performing the interpolating process on the plural lattice points in the correction area (step S310). That is, the correction values of the lattice points are calculated through the interpolating operation so that the correction target color can be obtained at the coordinate point of the correction object color and the correction values are “0” in the boundary of the correction area. Then, the RGB image data of the lattice points in the color correction table are corrected on the basis of the correction value calculated in the above-mentioned way (step S312). As a result, the color correction table which allows the correction object color to be converted into the desired color can be obtained for the correction object color selected in step S200.

Next, it is determined whether another candidate color should be corrected (step S314). When any candidate color of which the “set” button is not selected remains in the picture for selecting the correction object color shown in FIG. 18, it is determined that the candidate color should be corrected (No in step S314), a new correction object color is selected (step S300), and then the series of processes described above are performed. When the “set” buttons of all the candidate colors are selected by repeating such a series of processes, it is determined that all the candidate colors have been corrected (Yes in step S314) and the color correction table setting process according to the second embodiment shown in FIG. 17 is ended.

In the color correction table setting process according to the second embodiment described above, the correction target color is not selected from the plural candidate colors set in advance, but a user's desirable color can be obtained through adjustment before printing an image. Accordingly, since the user's desirable color can be set as the correction target color, it is possible to print a color image with a more preferable impression.

When the user obtains a correction target color through the adjustment, the hue component, the saturation component, and the brightness component can be independently changed. That is, there does not occur that the saturation or the brightness is changed when it is intended to adjust the hue or that the hue or the brightness is changed when it is intended to adjust the saturation. Accordingly, even a user lack of special knowledge and experience can obtain the desirable color through adjustment and print a color image with a more preferable impression.

### F. MODIFIED EXAMPLE

The color correction table setting processes according to the above-mentioned embodiments have several modified examples. Hereinafter, the modified examples are described in brief.

### (1) First Modified Example

In the color correction table setting processes according to the above-mentioned embodiments, it has been described that the color to be corrected (correction object color) is selected from plural colors set in advance. However, the correction object color may vary depending on color images to be printed. Accordingly, the correction object color may be selected from the color image to be printed.

FIG. 19 is an explanatory diagram illustrating a state where the correction object color is set from the color image to be printed in the color correction table setting process according to the first modified example. As shown in the figure, in the first modified example, the color image to be printed is displayed on the screen of the operation panel 300 or on a screen of a computer 30 independently of the printing apparatus 10, and then a portion of an image of which a color should be corrected is specified on the screen. Of course, accurate colors may be confirmed from the actually printed image and only the position to be corrected may be specified on the screen. The area indicated by a dotted rectangular in the figure represents the specified area in the image.

For example, when it is intended to print the blue sky with a clearer color, a partial area of the sky is specified as indicated by area A in the figure. Then, average values of the hue, the saturation, and the brightness in the specified area are calculated and the obtained color is set as the correction object color. For example, when it is intended to print the red color of a sail portion of a yacht with a more peaceful color, the average values of the hue, the saturation, and the brightness are calculated and are set for the correction object target, by specifying the corresponding portion as indicated by area B in the figure. By correcting the set correction object color by the use of the above-mentioned processes, it is possible to print a color image with a more preferable impression.

According to the first modified example, since a color to be corrected is directly specified on the basis of a color image to be printed, it is possible to specify a proper color and to print a color image with a more preferable impression.

### (2) Second Modified Example

In the above-mentioned embodiments, it has been described that the area around the specified correction object color is set as the correction area which is affected by the correction. That is, at the time of setting the correction area, it has been described that the correction object color is considered but the correction target color is not considered. However, when the correction value applied to the correction object color is greater relative to the correction area (or when the size of the correction area is smaller relative to the correction value), the correction area may be set so as to include the correction object color and the correction target color.

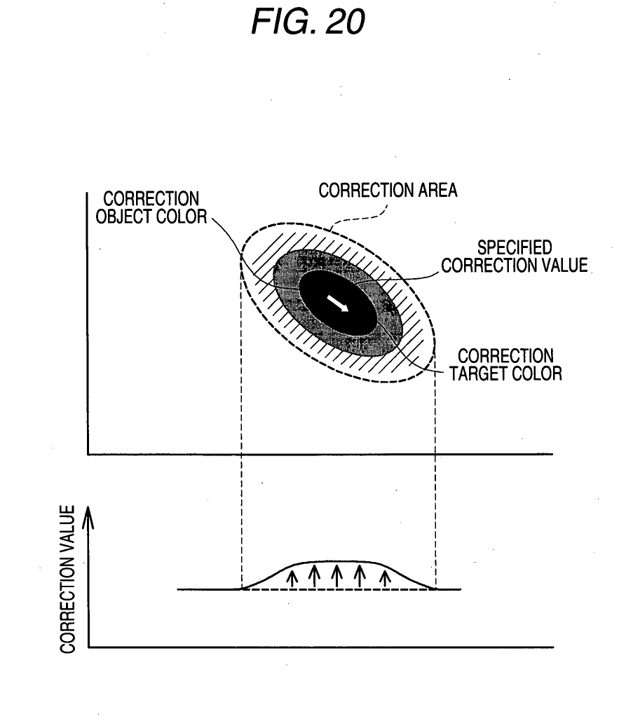

FIG. 20 is an explanatory diagram conceptually illustrating the correction area set to include the correction object color and the correction target color in the color correction table setting process according to the second modified example. In this way, by setting the correction area to include the correction object color and the correction target color, there is no possibility that a portion in which the color abruptly varies occurs to give an unnatural impression, even when the correction value of the color is large or when the color having a very narrow range of color is corrected (when the correction area is small). As a result, it is possible to print a color image that is naturally corrected into a desired color to give a desirable impression.

While a printing apparatus has been described with reference to the above-mentioned embodiments, the invention is not limited to the above-mentioned embodiments, but may be modified in various forms without departing from the gist of the invention.

What is claimed is:

1. An image processing method of processing color image data, comprising:
holding a correction object color which is a color to be corrected and a correction value of the correction object color at least at a time when starting an operation of correcting the color image data;
generating a correction area including a coordinate point corresponding to the correction object color in a predetermined color space;
generating a correction characteristic that the color is corrected within the correction area and the correction value decreases as it gets closer to an edge of the correction area from the coordinate point of the correction object color, based on the correction object color and the correction value; and
correcting the color image data in accordance with the generated correction characteristic.

2. The image processing method according to claim 1, further comprising:
setting the correction object color.

3. The image processing method according to claim 2, further comprising:
storing a plurality of correction object candidate colors which are candidates of the color object color, wherein
the correction object color is set by selecting the correction object color from the stored correction object candidate colors.

4. The image processing method according to claim 2, further comprising:
outputting a color image based on the received color image data;
specifying a partial area of the output color image; and
acquiring a specified area color which is a color representative of the specified area, based on the color image data, wherein
the specified area color is set as the correction object color.

5. The image processing method according to claims 2, further comprising:
storing a plurality of correction target candidate colors which are candidates of a correction target color which should be obtained by performing a correction operation on the correction object color, wherein
the correction object color is set by selecting the correction target color for the correction object color from the plurality of correction target candidate colors.

6. The image processing method according to claim 1, further comprising:
setting a correction value to be applied to the correction object color.

7. The image processing method according to claim 6, wherein
in the setting process, at least one of a hue component and a saturation component of the correction value to be applied to the correction object dolor is set.

8. The image processing method according to claim 1, further comprising:
converting the correction value of the correction object color into a correction value of a hue component, a saturation component and a brightness component, wherein
in the generating process of the correction characteristic, the correction characteristic of the hue component, the saturation component and the brightness component is generated.

9. The image processing method according to claim 1, further comprising:
changing the correction area set in the color space.

10. An image printing method of printing a color image, incorporating the image processing method according to claim 1, the image printing method comprising:
forming the color image based on the corrected color image data; and
printing the color image.

11. A method of setting a color correction table to which is referred to correct first color image data to obtain second color image data and in which the first color image data and the second color image data are correlated with each other, the method comprising:
holding a correction object color which is a color to be corrected and a correction value of the correction object color at least at a time when starting an operation of correcting the first color image data;
generating a correction area including a coordinate point corresponding to the correction object color in a predetermined color space;
generating a correction characteristic that the color is corrected within the correction area and the correction value decreases as it gets closer to an edge of the correction area from the coordinate point of the correction object color, based on the correction object color and the correction value;
correcting the first color image data in accordance with the generated correction characteristic to obtain the second color image data; and
storing the second color image data so as to be correlated with the first color image data.

12. A computer-readable recording medium in which a computer program causing a computer to execute the method according to claim 1 is recorded.

13. A computer-readable recording medium in which a computer program causing a computer to execute the method according to claim 10 is recorded.

14. A computer-readable recording medium in which a computer program causing a computer to execute the method according to claim 11 is recorded.

15. An image processing apparatus, operable to receive color image data and hold a correction object color which is a color to be corrected and a correction value of the correction object color at least at a time when correcting the color image data, the image processing apparatus comprising:
a correction area generator, operable to generate a correction area including a coordinate point corresponding to the correction object color in a color space;
a correction characteristic generator, operable to generate a correction characteristic that the color is corrected within the correction area and the correction value decreases as it gets closer to an edge of the correction area from the coordinate point of the correction object color, based on the correction object color and the correction value; and
an image data corrector, operable to correct the color image data in accordance with the generated correction characteristic.

16. A printing apparatus incorporating the image processing apparatus according to claim 15, the printing apparatus comprising:
an image former, operable to form a color image based on the corrected color image data; and
a printer, operable to print the formed color image.
